(19) United States
(12) Patent Application Publication
(10) Pub. No.: US 2026/0164964 A1
(43) Pub. Date: Jun. 11, 2026

(54) DISPLAY DEVICE, ELECTRONIC DEVICE AND METHOD OF MANUFACTURING DISPLAY DEVICE

(71) Applicant: Samsung Display Co., Ltd., Yongin-Si (KR)

(72) Inventors: JUNYOUNG LEE, Yongin-si (KR); YOUN-WOONG KANG, Yongin-si (KR); SI JOON SONG, Yongin-si (KR); DONGHYUN LEE, Yongin-si (KR); JAEHAK LEE, Yongin-si (KR)

(21) Appl. No.: 19/181,684

(22) Filed: Apr. 17, 2025

(30) Foreign Application Priority Data
Jul. 2, 2024 (KR) 10-2024-0086962

(51) Int. Cl. H10K 59/131; H10K 59/12

(52) U.S. Cl. CPC H10K 59/131; H10K 59/1201

(57) ABSTRACT

A display device is disclosed that includes a display panel including a base layer that defines an opening and a plurality of pad electrodes exposed to an outside through the opening, a circuit board including a plurality of bump electrodes and electrically connected to the plurality of pad electrodes through the plurality of bump electrodes, and a plurality of metal patterns that electrically connects the plurality of pad electrodes and the plurality of bump electrodes. Each of the metal patterns includes a first metal pattern disposed between a pad electrode and a bump electrode and a second metal pattern disposed on the bump electrode and the first metal pattern.

### CROSS-REFERENCE TO RELATED APPLICATIONS

This application claims priority under 35 U.S.C. § 119 to Korean Patent Application No. 10-2024-0086962 filed on Jul. 2, 2024, in the Korean Intellectual Property Office, the disclosures of which are incorporated by reference herein in their entireties.

### BACKGROUND

Embodiments of the present disclosure described herein relate to a display device, an electronic device, and a method of manufacturing the display device.

Electronic devices such as smart phones, tablets, laptop computers, vehicle navigation systems, and smart televisions have been developed. These electronic devices are provided with display devices to provide information.

Various types of display devices are being developed to satisfy user experience (UX)/user interface (UI) of a user. The display devices are being developed to provide a wide display area and a narrow non-display area.

### SUMMARY

Embodiments of the present disclosure may provide a display device having a reduced non-display area, an electronic device, and a method of manufacturing a display device.

According to an embodiment, a display device includes a display panel a base layer that defines an opening and includes a plurality of pad electrodes exposed to an outside through the opening, a circuit board including a plurality of bump electrodes and electrically connected to the plurality of pad electrodes through the plurality of bump electrodes, and a plurality of metal patterns that electrically connects the plurality of pad electrodes to the plurality of bump electrodes. Each of the metal patterns includes a first metal pattern disposed between a pad electrode and a bump electrode and a second metal pattern disposed on the bump electrode and the first metal pattern.

According to an embodiment, an electronic device includes a housing, an electronic module disposed inside the housing, and a display device disposed to overlap the electronic module. The display device includes a display panel including a base layer that defines an opening and includes a plurality of pad electrodes exposed to an outside through the opening, a circuit board including a plurality of bump electrodes and electrically connected to the plurality of pad electrodes through the plurality of bump electrodes, and a plurality of metal patterns that electrically connect the plurality of pad electrodes and the plurality of bump electrodes. Each of the metal pattern includes a first metal pattern disposed between a pad electrode and a bump electrode and a second metal pattern disposed on the bump electrode and the first metal pattern.

According to an embodiment, a method of manufacturing a display device includes forming a first preliminary metal layer on a plurality of pad electrodes exposed through an opening defined in a base layer and arranged in a first direction, providing a plurality of bump electrodes arranged on the first preliminary metal layer and overlapping the plurality of pad electrodes in a plan view, hardening the first preliminary metal layer to form a first metal layer, forming a second preliminary metal layer disposed on the plurality of bump electrodes and the first metal layer, and forming a plurality of first metal patterns and a plurality of second metal patterns by patterning the first preliminary metal layer and the second preliminary metal layer. Each of the pad electrodes and each of the bump electrodes are electrically connected by a first metal pattern and a second metal pattern.

### BRIEF DESCRIPTION OF THE FIGURES

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of the electronic device according to an embodiment of the present disclosure.

FIG. 3 is a cross-sectional view of a display device along line I-I′ of FIG. 2.

FIG. 4 is a schematic cross-sectional view of a display module according to an embodiment of the present disclosure.

FIG. 5 is a plan view of a display panel according to an embodiment of the present disclosure.

FIG. 6 is a cross-sectional view of the display module according to an embodiment of the present disclosure.

FIG. 7 is a plan view of the display panel according to an embodiment of the present disclosure.

FIG. 8 is an enlarged view of a portion of the display device according to an embodiment of the present disclosure.

FIG. 9A is a cross-sectional view of the display device along line II-II′ of FIG. 8.

FIG. 9B is an enlarged view of area AA′ of FIG. 9A.

FIG. 10A is an enlarged view of the portion of the display device according to an embodiment of the present disclosure.

FIG. 10B is an enlarged view of the display panel according to an embodiment in which area AA′ illustrated in FIG. 9A is enlarged.

FIGS. 11A to 11G are views illustrating some of operations of a method of manufacturing the display device according to an embodiment of the present disclosure.

FIGS. 12A and 12B are views illustrating some of operations of a method of manufacturing the display device according to an embodiment of the present disclosure.

### DETAILED DESCRIPTION

Since the present disclosure is variously modified and has alternative forms, an embodiments thereof will be illustrated in the drawings and will be described herein in detail. However, it should be understood that the present disclosure is not limited to specific embodiments includes all changes, equivalents, and substitutes included in the spirit and scope of the appended claims.

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Further, the terms “under”, “beneath”, “on”, “above”, etc. are used to describe a relationship between components illustrated in the drawings. The terms that are relative in concept are described based on a direction illustrated in drawings.

Unless otherwise defined, all terms (including technical terms and scientific terms) used in the specification have the same meaning as commonly understood by those skilled in the art to which the present disclosure belongs. Further, terms defined should be construed as having the same meanings as those in the context of the related art, and are explicitly defined therein unless the terms are interpreted in an ideal or excessive formal meaning.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Hereinafter, embodiments of the present disclosure will be described with reference to the accompanying drawings.

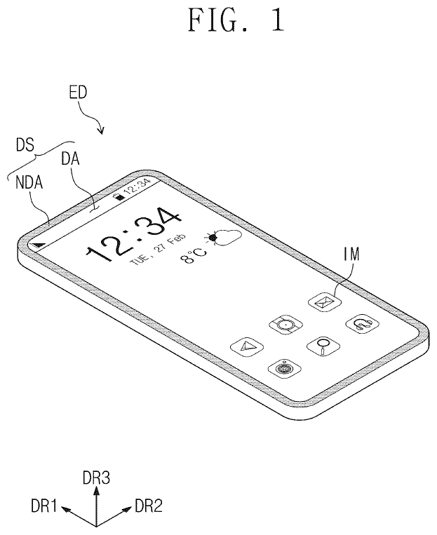

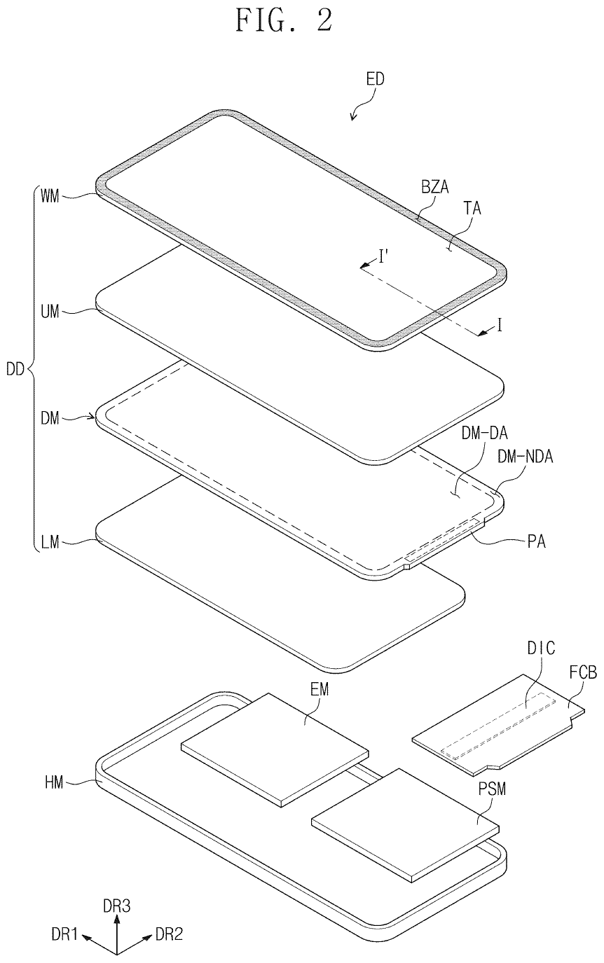

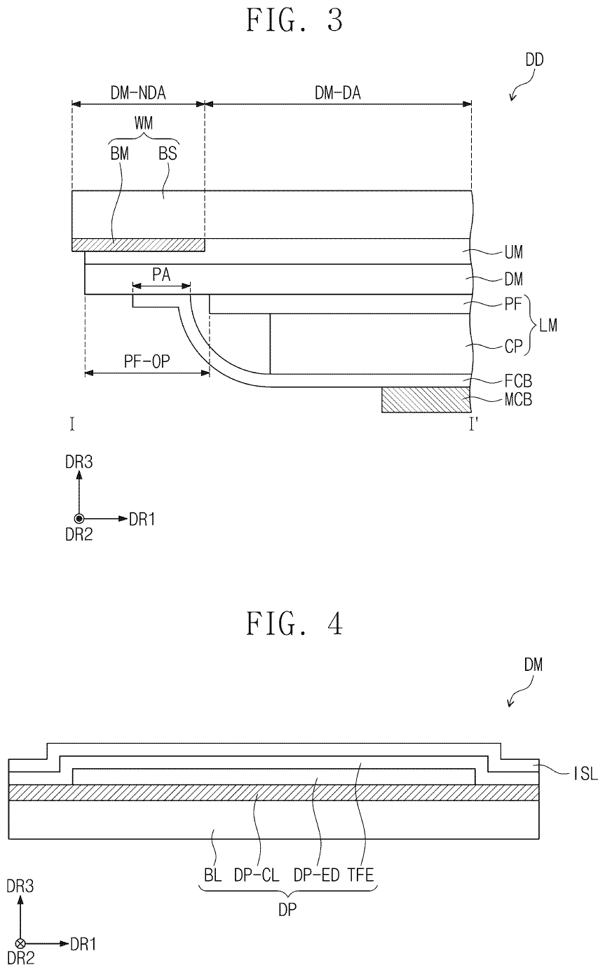

FIG. 1 is a perspective view of an electronic device according to an embodiment of the present disclosure. FIG. 2 is an exploded perspective view of the electronic device according to an embodiment of the present disclosure. FIG. 3 is a cross-sectional view of a display device along line I-I′ of FIG. 2.

Referring to FIG. 1, an electronic device ED according to an embodiment of the present disclosure may include a display surface DS defined by a first direction DR1 and a second direction DR2 intersecting the first direction DR1. The electronic device ED may provide an image IM to a user through the display surface DS.

The display surface DS may include a display area DA and a non-display area NDA around the display area DA. The display area DA may be an area that displays the image IM, and the non-display area NDA may be an area that does not display the image IM. The non-display area NDA may surround the display area DA. However, the present disclosure is not limited thereto, and the shape of the display area DA and the shape of the non-display area NDA may be modified.

Hereinafter, a direction substantially perpendicular to a plane defined by the first direction DR1 and the second direction DR2 is defined as a third direction DR3. The third direction DR3 serves as a standard for distinguishing a front surface and a rear surface of each of members. In the specification, the wording “on a plane” may be defined as a state in which the electronic device ED is viewed from the third direction DR3.

In an embodiment of the present disclosure, the electronic device ED may be a foldable electronic device that may be folded about a folding axis. The folding axis may be parallel to the first direction DR1 or the second direction DR2, and a folding area may be defined in a portion of the display area DA. The electronic device ED may be in-folded such that the display areas DA face each other or out-folded such that the display areas DA are folded away from each other.

As illustrated in FIG. 2, the electronic device ED may include a display device DD, an electronic module EM, a power supply module PSM, and a housing HM. FIG. 2 schematically illustrates the electronic device ED, and the electronic device ED may further include a mechanical structure (e.g., a hinge) for controlling an operation (e.g., folding or rolling) of the display device DD.

The display device DD generates the image IM and senses an external input. The display device DD includes a window WM, an upper member UM, a display module DM, a lower member LM, a circuit board (or flexible circuit board) FCB, a driving chip DIC. The upper member UM includes members arranged on the display module DM, and the lower member LM includes members arranged under the display module DM.

The window WM provides a front surface of the electronic device ED. The window WM includes a transmissive area TA and a bezel area BZA. The display area DA and the non-display area NDA of the display surface DS illustrated in FIG. 1 are defined by the transmissive area TA and the bezel area BZA. The transmissive area TA is an area through which an image passes, and the bezel area BZA is an area that covers a structure/member disposed under the window WM.

The display module DM includes a display area DM-DA and a non-display area DM-NDA corresponding to the display area DA and the non-display area NDA illustrated in FIG. 1. In the specification, an expression “an area/part and an area/part correspond to each other” means that the area/part and the area/part overlap each other and is not limited to the same area.

A pad area PA is disposed on one side of the non-display area DM-NDA. The pad area PA is an area that is electrically bonded (or connected) to the circuit board FCB, which will be described below. In an embodiment, the pad area PA is defined on a rear surface of the display module DM.

The display module DM has a substantially quadrangular shape. Here, the “substantially quadrangular shape” includes not only a quadrangular shape in the mathematical sense but also a shape similar to the quadrangular shape, which may be recognized as a quadrangular shape by the user. For example, a substantially quadrangular shape may include a quadrangular shape having rounded corner areas. Further, in the substantially quadrangular shape, edges of the display module DM are not limited to a straight shape, and the edges may include curved areas.

The upper member UM may include a protective film or an optical film. The optical film may include a polarizer and a retarder to reduce reflection of external light. The lower member LM may include a protective film that protects the display module DM, a support member that supports the display module DM, a digitizer, and the like. The upper member UM and the lower member LM will be described below in detail.

The circuit board FCB is disposed under the display module DM. The circuit board FCB may be bonded to a rear surface of the display module DM. The circuit board FCB electrically connects the display module DM and a main circuit board MCB (see FIG. 3). The circuit board FCB includes at least one insulating layer and at least one conductive layer. The conductive layer may include a plurality of signal lines.

The driving chip DIC may be mounted on the circuit board FCB. The driving chip DIC may include a driving circuit, for example, a data driving circuit, for driving pixels of the display module DM. FIG. 2 illustrates a structure in which the driving chip DIC is mounted on the circuit board FCB, but the present disclosure is not limited thereto. For example, the driving chip DIC may be mounted on the display module DM or the main circuit board MCB.

The electronic module EM may include a control module, a wireless communication module, an image input module, a sound input module, a sound output module, a memory, an external interface module, and the like. The electronic module EM may include the main circuit board MCB, and the modules may be mounted on the main circuit board MCB or may be electrically connected to the main circuit board MCB through the flexible circuit board. The electronic module EM is electrically connected to the power supply module PSM.

Although not separately illustrated, the electronic device ED may further include an electro-optical module. The electro-optical module may be an electronic component that outputs or receives an optical signal. The electro-optical module may include a camera module or a proximity sensor. The camera module may capture an external image through a portion of the display module DM.

The housing HM illustrated in FIG. 2 is coupled to the display device DD, particularly, the window WM, and accommodates the other modules. It is illustrated that the housing HM has an integral shape, but the present disclosure is not limited thereto. The housing HM may include a plurality of portions (e.g., a side edge portion and a bottom portion) coupled to each other.

Referring to FIG. 3, the window WM may include a base substrate BS and a bezel pattern BM disposed on a lower surface of the base substrate BS. The base substrate BS may include a synthetic resin film or a glass substrate. The base substrate BS may have a multi-layer structure. The base substrate BS may include a thin film glass substrate, a protective film disposed on the thin film glass substrate, and an adhesive layer that couples the thin film glass substrate and the protective film.

The bezel pattern BM, which is a colored light shielding film, may be formed by, for example, a coating method. The bezel pattern BM may include a base material and a dye or a pigment mixed with the base material. The bezel pattern BM overlaps the non-display area NDA illustrated in FIG. 1 and the bezel area BZA illustrated in FIG. 2. The bezel pattern BM may be disposed on the lower surface of the base substrate BS. When the base substrate BS has a multi-layer structure, the bezel pattern BM may be disposed between interfaces defined by a plurality of layers. For example, the bezel pattern BM may be disposed between the thin film glass substrate and the protective film. Although not separately illustrated, the window WM may further include at least one of a hard coating layer, a fingerprint preventing layer, and a reflection preventing layer on an upper surface of the base substrate BS.

The upper member UM may include an upper film. The upper film may include a synthetic resin film. The synthetic resin film may include polyimide, polycarbonate, polyamide, triacetylcellulose, polymethylmethacrylate, or polyethylene terephthalate.

The upper film may absorb an external impact applied to a front surface of the display device DD. In an embodiment of the present disclosure, the display module DM may include a color filter that replaces a polarizing film as a reflection preventing member, and therefore, impact strength of the front surface of the display device DD may be reduced. The upper film may compensate for the reduced impact strength by applying the color filter.

The upper member UM overlaps the bezel area BZA (see FIG. 2) and the transmissive area TA (see FIG. 2). The upper member UM may overlap only a portion of the bezel area BZA. The portion of the bezel pattern BM may be exposed from the upper member UM. In an embodiment of the present disclosure, the upper member UM may be omitted. In an embodiment of the present disclosure, the upper member UM may be replaced with an optical film including a polarizer and a retarder.

Although not illustrated, an adhesive layer that couples the upper member UM and the window WM may be further included between the upper member UM and the window WM. The adhesive layer may be a pressure sensitive adhesive (PSA) film or an optically clear adhesive (OCA) member.

The display module DM is disposed under the upper member UM. The display module DM overlaps the bezel area BZA and the transmissive area TA. The display module DM may completely overlap the upper member UM within the bezel area BZA. A side surface of the display module DM may be aligned with a side surface of the upper member UM, and an edge of the display module DM may be aligned with an edge of the upper member UM.

The pad area PA of the display module DM within the bezel area BZA may overlap the upper member UM. A portion of the display module DM corresponding to the pad area PA may be coupled to a lower surface of the upper member UM by the adhesive layer. The pad area PA overlaps the upper member UM, a portion of the display module DM, which overlaps the pad area PA, is coupled to the upper member UM, and thus the upper member UM may sufficiently support the pad area PA when the circuit board FCB is bonded to the pad area PA.

The lower member LM may include a lower film PF and a cover panel CP. In an embodiment of the present disclosure, the lower member LM may further include a support plate and a digitizer.

The lower film PF may expose the pad area PA of the display module DM. The lower film PF may have a smaller size than that of the display module DM. For example, the lower film PF may overlap only the display area DM-DA of the display module DM. An open area PF-OP corresponding to the non-display area DM-NDA may be defined in the lower film PF. Alternatively, the lower film PF may have a size that substantially corresponds to the display module DM. In this case, the open area PF-OP corresponding to the pad area PA may be defined in the lower film PF. The pad area PA may be exposed through the open area PF-OP.

The cover panel CP may be disposed under the lower film PF. The cover panel CP may increase resistance against a compressive force generated by external pressure. Thus, the cover panel CP may serve to prevent deformation of the display module DM. The cover panel CP may include a flexible plastic material such as polyimide or polyethylene terephthalate. Further, the cover panel CP may be a colored film having a low light transmittance. The cover panel CP may absorb a light input from the outside. For example, the cover panel CP may be a black synthetic resin film. When the display device DD is viewed from an upper side of the window WM, components arranged under the cover panel CP may not be visually recognized by the user.

Although not illustrated, a support plate may be further disposed under the cover panel CP. The support plate may include a metal material having high strength. The support plate may also include a reinforced fiber composite. The support plate may include a reinforced fiber disposed inside a matrix part. The reinforced fiber may be a carbon fiber or a glass fiber. The matrix part may include a polymer resin. The matrix part may include a thermoplastic resin. For example, the matrix part may include a polyamide-based resin or a polypropylene-based resin. For example, the reinforced fiber composite may be carbon fiber reinforced plastic (CFRP) or glass fiber reinforced plastic (GFRP).

The main circuit board MCB may be disposed on a lower surface of the circuit board FCB. The circuit board FCB may include an insulating film and conductive wiring lines mounted on the insulating film. The main circuit board MCB may include signal lines and electronic elements, which are not illustrated. The electronic elements may be connected to the signal lines and electrically connected to the display module DM. The electronic elements generate various electrical signals, for example, signals for generating an image or signals for sensing an external input, or process sensed signals. The one main circuit board MCB may be provided to correspond to each electrical signal to be generated and processed, three or more main circuit boards MCB may be provided, and the present disclosure is not limited to an embodiment.

Although not illustrated, the main circuit board MCB may include the driving chip DIC (see FIG. 2) mounted inside the main circuit board MCB.

Referring to FIGS. 2 and 3, the circuit board FCB is coupled (rear-bonded) to the rear surface of the display module DM. Because the non-display area DM-NDA of the display module DM is not bent, defects that occur when the non-display area DM-NDA of the display module DM is bent may be prevented. Further, an area of the bezel area BZA of the window WM for covering the non-display area DM-NDA of the display module DM may be reduced.

FIG. 4 is a schematic cross-sectional view of a display module according to an embodiment of the present disclosure.

Referring to FIG. 4, the display module DM may include the display panel DP and an input sensing layer ISL. The display panel DP may include a base layer BL, a circuit layer DP-CL, a display element layer DP-ED, and an encapsulation layer TFE.

The circuit layer DP-CL is disposed on an upper surface of the base layer BL. The base layer BL may be a flexible substrate that may be bent, folded, and rolled. The base layer BL may be a glass substrate, a metal substrate, a polymer substrate, or the like. However, an embodiment of the present disclosure is not limited thereto, and the base layer BL may be an inorganic layer, an organic layer, or a composite material layer. Substantially, the base layer BL has the same shape as that of the display panel DP.

The base layer BL may have a multi-layer structure. For example, the base layer BL may include a first synthetic resin layer, a second synthetic resin layer, and an inorganic layer disposed therebetween. Each of the first synthetic resin layer and the second synthetic resin layer may include a polyimide-based resin, but the present disclosure is not particularly limited thereto.

The circuit layer DP-CL may be disposed on the base layer BL. The circuit layer DP-CL may include a plurality of insulating layers, a plurality of semiconductor patterns, a plurality of conductive patterns, and the signal lines. The circuit layer DP-CL may include a driving circuit of a pixel. Hereinafter, unless otherwise specified, when component “A” and component “B” are arranged on the same layer, it is interpreted that component “A” and component “B” are formed by the same process and thus include the same material or have the same laminated structure. The conductive patterns or the semiconductor patterns arranged on the same layer may be interpreted as described above.

The display element layer DP-ED may be disposed on the circuit layer DP-CL. The display element layer DP-ED may include a light emitting element. For example, the light emitting element may include an organic light emitting material, an inorganic light emitting material, an organic-inorganic light emitting material, a quantum dot, a quantum rod, a micro-light emitting diode (LED), or a nano-LED.

The encapsulation layer TFE may be disposed on the display element layer DP-ED. The encapsulation layer TFE may protect the display element layer DP-ED, i.e., the light emitting element, from foreign substances such as moisture, oxygen, and dust particles. The encapsulation layer TFE may include at least one inorganic encapsulation layer. The encapsulation layer TFE may include a laminated structure of a first inorganic encapsulation layer, an organic encapsulation layer, and a second inorganic encapsulation layer.

The input sensing layer ISL may directly be disposed on the display panel DP. The input sensing layer ISL may sense an input of the user using, for example, an electromagnetic induction method or a capacitance method. The display panel DP and the input sensing layer ISL may be formed through a continuous process. Here, the aspect that “the input sensing layer ISL is directly disposed on the display panel DP” may mean that a third component is not disposed between the input sensing layer ISL and the display panel DP. That is, a separate adhesive layer may not be disposed between the input sensing layer ISL and the display panel DP.

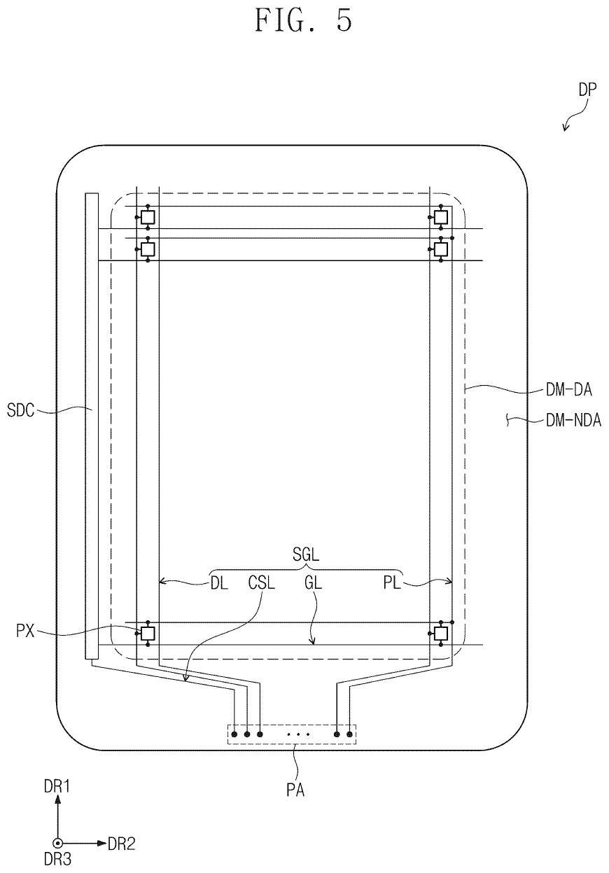

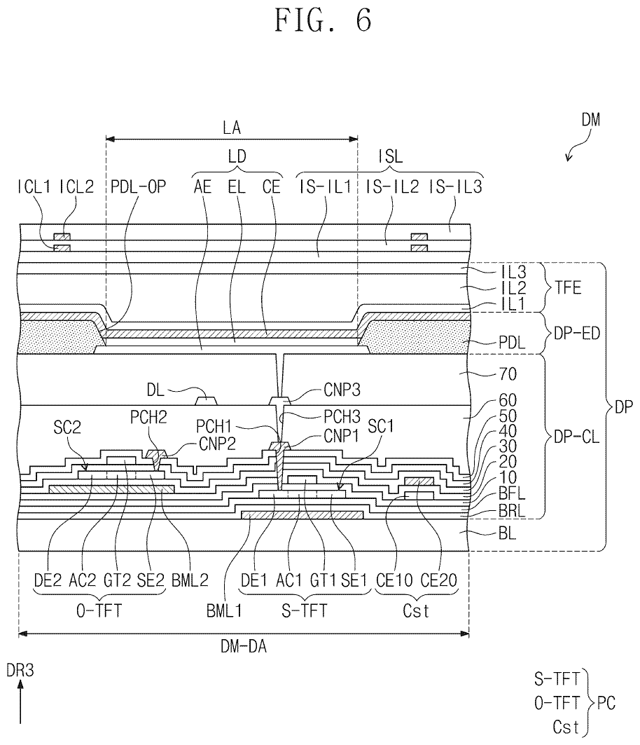

FIG. 5 is a plan view of the display panel according to an embodiment of the present disclosure. FIG. 6 is a cross-sectional view of the display module according to an embodiment of the present disclosure.

As illustrated in FIG. 5, the display panel DP may include a scan driving circuit SDC, a plurality of signal lines SGL, and a plurality of pixels PX. The plurality of pixels PX are arranged in the display area DM-DA. Each of the pixels PX includes a light emitting element and a pixel driving circuit connected thereto. The scan driving circuit SDC, the plurality of signal lines SGL, and the pixel driving circuit may be included in the circuit layer DP-CL illustrated in FIG. 4.

The scan driving circuit SDC may include a gate driving circuit. The gate driving circuit generates a plurality of scan signals and sequentially outputs the plurality of scan signals to a plurality of scan lines GL, which will be described below. The scan driving circuit SDC may further include a light emitting driving circuit that is distinguished from the gate driving circuit. The light emitting driving circuit may output scan signals to another group of scan lines.

The scan driving circuit SDC may include a plurality of thin film transistors formed through the same process as that of the pixel driving circuit, for example, a low temperature polycrystalline silicon (LTPS) process or a low temperature polycrystalline oxide (LTPO) process.

The plurality of signal lines SGL include the scan lines GL, data lines DL, a power line PL, and a control signal line CSL. Each of the scan lines GL is connected to a corresponding pixel PX among the plurality of pixels PX, and each of the data lines DL is connected to a corresponding pixel PX among the plurality of pixels PX. The power line PL is connected to the plurality of pixels PX. The data lines DL provide data signals to the pixels PX. The control signal line CSL may provide control signals to the scan driving circuit SDC.

A plurality of power lines PL may be provided. For example, the power line PL may include a first power line that receives a first power voltage and a second power line that receives a second power voltage having a higher level than that of the first power voltage. The first power voltage is provided to the pixels PX through the first power line, and the second power voltage is provided to the pixels PX through the second power line. Although the one control signal line CSL is illustratively illustrated in FIG. 5, a plurality of control signal lines CSL may be provided.

The scan lines GL, the data lines DL, and the power line PL may overlap the display area DM-DA and the non-display area DM-NDA, and the control signal line CSL may overlap the non-display area DM-NDA. Distal ends of the plurality of signal lines SGL may be aligned on one side of the non-display area DM-NDA. The plurality of signal lines SGL may have an integral shape but may include a plurality of parts arranged on different layers. Different parts divided by the insulating layer may be connected through a contact hole passing through the insulating layer. For example, the data lines DL may include a first part disposed in the display area DM-DA and a second part disposed in the non-display area DM-NDA and disposed on a different layer from that of the first part. The first part and the second part may include different materials and have different laminated structures.

The plurality of signal lines SGL may be electrically connected to the main circuit board MCB illustrated in FIG. 3 through the pad area PA.

FIG. 6 illustrates a cross section of the display module DM corresponding to the pixel PX of FIG. 5.

A pixel driving circuit PC that drives a light emitting element LD may include a plurality of pixel driving elements. The pixel driving circuit PC may include a plurality of transistors S-TFT and O-TFT and a capacitor Cst. The plurality of transistors S-TFT and O-TFT may include the silicon transistor S-TFT and the oxide transistor O-TFT. FIG. 6 illustratively illustrates the silicon transistor S-TFT and the oxide transistor O-TFT. The pixel driving circuit PC of FIG. 6 is merely an embodiment, and the configuration of the pixel driving circuit PC is not necessarily limited thereto. The pixel driving circuit PC may include only one type of transistor among the silicon transistor S-TFT and the oxide transistor O-TFT.

Referring to FIG. 6, the base layer BL is illustrated as a single layer. The base layer BL may include a synthetic resin such as polyimide. The base layer BL may be formed by coating a working substrate (or a carrier substrate) with a synthetic resin layer. When the display module DM is completed through a follow-up process, the working substrate may be removed.

A first shielding electrode (or a shielding electrode) BML1 may be disposed on the base layer BL. The first shielding electrode BML1 may receive a bias voltage. The first shielding electrode BML1 may also receive the first power voltage. The first shielding electrode BML1 may prevent an electrical potential due to a polarization phenomenon from affecting the silicon transistor S-TFT. The first shielding electrode BML1 may prevent an external light from reaching the silicon transistor S-TFT. In an embodiment of the present disclosure, the first shielding electrode BML1 may be a floating electrode that is isolated from other electrodes or wiring lines. The first shielding electrode BML1 may be disposed to correspond to the silicon transistor S-TFT. The first shielding electrode BML1 may include a metal, for example, molybdenum.

A barrier layer BRL may be disposed on the base layer BL and the first shielding electrode BML1. The barrier layer BRL prevents inflow of foreign substances from the outside. The barrier layer BRL may include at least one inorganic layer. The barrier layer BRL may include a silicon oxide layer and a silicon nitride layer. Each of the silicon oxide layer and the silicon nitride layer may be provided in plurality and the silicon oxide layers and the silicon nitride layers may be alternately laminated.

A buffer layer BFL may be disposed on the barrier layer BRL. The buffer layer BFL may prevent metal atoms or impurities from being diffused from the base layer BL to an upper first semiconductor pattern SC1. The buffer layer BFL may include at least one inorganic layer. The buffer layer BFL may include a silicon oxide layer and a silicon nitride layer.

The first semiconductor pattern SC1 may be disposed on the buffer layer BFL. The first semiconductor pattern SC1 may include a silicon semiconductor. For example, the silicon semiconductor may include amorphous silicon, polycrystalline silicon, and the like. For example, the first semiconductor pattern SC1 may include a low-temperature polysilicon.

The first semiconductor pattern SC1 may have different electrical properties depending on whether the first semiconductor pattern SC1 is doped. The first semiconductor pattern SC1 may include a first area having high conductivity and a second area having low conductivity. The first area may be doped with an N-type dopant or a P-type dopant. A P-type transistor may include a doped area doped with the P-type dopant, and an N-type transistor may include a doped area doped with the N-type dopant. The second area may be a non-doped area or may be an area doped at a concentration lower than that of the first area. In an embodiment, the first semiconductor pattern SC1 may be the N-type transistor.

A conductivity of the first area is greater than a conductivity of the second area, and the first area may substantially serve as an electrode or a signal line. The second area may substantially correspond to a channel area (or an active area) of the transistor. In other words, a portion of the first semiconductor pattern SC1 may be a channel of the transistor, another portion of the first semiconductor pattern SC1 may be a source or drain of the transistor, and still another portion of the first semiconductor pattern SC1 may be a connection electrode or connection signal line.

A source area SE1, a channel area AC1 (or an active area), and a drain area DE1 of the silicon transistor S-TFT may be formed from the first semiconductor pattern SC1. The source area SE1 and the drain area DE1 may extend in opposite directions from the channel area AC1 on a cross-section.

A first insulating layer 10 may be disposed on the buffer layer BFL. The first insulating layer 10 may cover the first semiconductor pattern SC1. The first insulating layer 10 may be an inorganic layer. The first insulating layer 10 may be a single-layer silicon oxide layer. The first insulating layer 10 as well as the inorganic layer of the circuit layer DP-CL, which will be described below, may have a single-layer or multi-layer structure and include at least one of the above-described materials, but the present disclosure is not limited thereto.

A gate (or a gate electrode) GT1 of the silicon transistor S-TFT is disposed on the first insulating layer 10. The gate GT1 may be a portion of a metal pattern. The gate GT1 overlaps the channel area AC1. In a process of doping the first semiconductor pattern SC1, the gate GT1 may serve as a mask. A first electrode CE10 of the capacitor Cst is disposed on the first insulating layer 10. Unlike the illustration of FIG. 6, the first electrode CE10 may have an integrated shape with the gate GT1.

A second insulating layer 20 may be disposed on the first insulating layer 10 and cover the gate GT1. In an embodiment of the present disclosure, an upper electrode overlapping the gate GT1 may be further disposed on the second insulating layer 20. A second electrode CE20 overlapping the first electrode CE10 may be disposed on the second insulating layer 20. The upper electrode may have an integral shape with the second electrode CE20 in a plan view.

A second shielding electrode BML2 is disposed on the second insulating layer 20. The second shielding electrode BML2 may be disposed to correspond to the oxide transistor O-TFT. In an embodiment of the present disclosure, the second shielding electrode BML2 may be omitted. According to an embodiment of the present disclosure, the first shielding electrode BML1 may extend to a lower portion of the oxide transistor O-TFT and replace the second shielding electrode BML2.

A third insulating layer 30 may be disposed on the second insulating layer 20. A second semiconductor pattern SC2 may be disposed on the third insulating layer 30. The second semiconductor pattern SC2 may include a channel area AC2 of the oxide transistor O-TFT. The second semiconductor pattern SC2 may include a metal oxide semiconductor. The second semiconductor pattern SC2 may include a transparent conductive oxide (TCO) such as an indium tin oxide (ITO), an indium zinc oxide (IZO), an indium gallium zinc oxide (IGZO), a zinc oxide (ZnOₓ), or an indium oxide (In₂O₃).

The metal oxide semiconductor may include a plurality of areas SE2, AC2, and DE2 divided according to whether the TCO is reduced. An area (hereinafter, referred to as a reduced area), in which the TCO is reduced, has higher conductivity than that of an area (hereinafter, a non-reduced area), in which the TCO is not reduced. The reduced area substantially serves as the source area/drain area of the transistor or the signal line. The non-reduced area substantially corresponds to a semiconductor area (or a channel area) of the transistor. In other words, a partial area of the second semiconductor pattern SC2 may be the semiconductor area of the transistor, another partial area thereof may be the source area SE2/the drain area DE2 of the transistor, and still another partial area thereof may be a signal transmitting area.

A fourth insulating layer 40 may be disposed on the third insulating layer 30. As illustrated in FIG. 6, the fourth insulating layer 40 may cover the second semiconductor pattern SC2. In an embodiment of the present disclosure, the fourth insulating layer 40 may be an insulating pattern that overlaps a gate GT2 of the oxide transistor O-TFT and exposes the source area SE2 and the drain area DE2 of the oxide transistor O-TFT.

The gate GT2 of the oxide transistor O-TFT is disposed on the fourth insulating layer 40. The gate GT2 of the oxide transistor O-TFT may be a portion of the metal pattern. The gate GT2 of the oxide transistor O-TFT overlaps the channel area AC2.

A fifth insulating layer 50 may be disposed on the fourth insulating layer 40, and the fifth insulating layer 50 may cover the gate GT2. Each of the first insulating layer 10 to the fifth insulating layer 50 may be an inorganic layer.

A conductive layer may be disposed on the fifth insulating layer 50. In the present disclosure, the conductive layer may include a first connection pattern CNP1 and a second connection pattern CNP2. The first connection pattern CNP1 and the second connection pattern CNP2 may be formed through the same process and thus may have the same material and the same laminated structure. The first connection pattern CNP1 may be connected to the drain area DE1 of the silicon transistor S-TFT through a first pixel contact hole PCH1 passing through the first to fifth insulating layers 10, 20, 30, 40, and 50. The second connection pattern CNP2 may be connected to the source area SE2 of the oxide transistor O-TFT through a second pixel contact hole PCH2 passing through the fourth and fifth insulating layers 40 and 50. The connection relationship between the first connection pattern CNP1 and the second connection pattern CNP2 for the silicon transistor S-TFT and the oxide transistor O-TFT is not necessarily limited thereto.

A sixth insulating layer 60 may be disposed on the fifth insulating layer 50. A third connection pattern CNP3 may be disposed on the sixth insulating layer 60. The third connection pattern CNP3 may be connected to the first connection pattern CNP1 through a third pixel contact hole PCH3 passing through the sixth insulating layer 60. The data line DL may be disposed on the sixth insulating layer 60. A seventh insulating layer 70 may be disposed on the sixth insulating layer 60 and cover the third connection pattern CNP3 and the data line DL. The third connection pattern CNP3 and the data line DL may be formed through the same process and thus may have the same material and the same laminated structure. Each of the sixth insulating layer 60 and the seventh insulating layer 70 may be an organic layer.

The first shielding electrode BML1, the gate GT1 of the silicon transistor S-TFT, the second electrode CE20, and the gate GT2 of the oxide transistor O-TFT may include molybdenum (Mo), an alloy containing molybdenum, titanium (Ti), or an alloy containing titanium, which has excellent heat resistance. The first connection pattern CNP1 and the second connection pattern CNP2 may include aluminum, which has high electrical conductivity. The first connection pattern CNP1 and the second connection pattern CNP2 may have a three-layer structure in which titanium/aluminum/titanium are laminated.

The light emitting element LD may include an anode AE (or a first electrode), a light emitting layer EL, and a cathode CE (or a second electrode). The anode AE of the light emitting element LD may be disposed on the seventh insulating layer 70. The anode AE may be a transmissive electrode, a semi-transmissive electrode, or a reflective electrode. The anode AE may include a laminated structure in which ITO/Ag/ITO are sequentially laminated. The positions of the anode AE and the cathode CE may be changed to each other.

A pixel defining film PDL may be disposed on the seventh insulating layer 70. The pixel defining film PDL may be an organic layer. The pixel defining film PDL may have a property of absorbing a light, and for example, the pixel defining film PDL may have a black color. The pixel defining film PDL may include a black coloring agent. The black coloring agent may include black dye and black pigment. The black coloring agent may include carbon black, a metal such as chromium, or an oxide thereof. The pixel defining film PDL may correspond to a light shielding pattern having light shielding characteristics.

The pixel defining film PDL may cover a portion of the anode AE. For example, an opening PDL-OP through which the portion of the anode AE is exposed may be defined in the pixel defining film PDL. A light emitting area LA may be defined to correspond to the opening PDL-OP. In an embodiment of the present disclosure, a hole control layer may be disposed between the anode AE and the light emitting layer EL. The hole control layer may include a hole transport layer and may further include a hole injection layer. An electron control layer may be disposed between the light emitting layer EL and the cathode CE. The electron control layer may include an electron transport layer and may further include an electron injection layer.

The encapsulation layer TFE may cover the light emitting element LD. The encapsulation layer TFE may include a first encapsulation insulating layer IL1, a second encapsulation insulating layer IL2, and a third encapsulation insulating layer IL3. However, the present disclosure is not limited thereto, and the encapsulation layer TFE may further include a plurality of inorganic layers and a plurality of organic layers.

The first encapsulation insulating layer IL1 may be an inorganic layer. The first encapsulation insulating layer IL1 may prevent external moisture or oxygen from penetrating into the light emitting element LD. For example, the first encapsulation insulating layer IL1 may include a silicon nitride, a silicon oxide, or a compound obtained by combining them. The first encapsulation insulating layer IL1 may be formed through a chemical vapor deposition process.

The second encapsulation insulating layer IL2 may be an organic layer. The second encapsulation insulating layer IL2 may be disposed on the first encapsulation insulating layer IL1 and may be in contact with the first encapsulation insulating layer IL1. The second encapsulation insulating layer IL2 may provide a flat surface onto the first encapsulation insulating layer IL1. Curves formed in an upper surface of the first encapsulation insulating layer IL1 and particles present on the first encapsulation insulating layer IL1 are covered by the second encapsulation insulating layer IL2, and thus a surface condition of the upper surface of the first encapsulation insulating layer IL1 may be prevented from affecting components formed on the second encapsulation insulating layer IL2. Further, the second encapsulation insulating layer IL2 may alleviate stresses between contact layers. The second encapsulation insulating layer IL2 may be formed through a solution process such as spin coating, slit coating, and an inkjet process.

The third encapsulation insulating layer IL3 is disposed on the second encapsulation insulating layer IL2 and covers the second encapsulation insulating layer IL2. The third encapsulation insulating layer IL3 may be stably formed on a relatively flat surface as compared to a state in which the third encapsulation insulating layer IL3 is disposed on the first encapsulation insulating layer IL1. The third encapsulation insulating layer IL3 encapsulates moisture released from the second encapsulation insulating layer IL2 and thus prevents the moisture from being introduced to the outside.

The third encapsulation insulating layer IL3 may be optically transparent. For example, the third encapsulation insulating layer IL3 may have a visible light transmittance of about 90% or more. The third encapsulation insulating layer IL3 may have a relatively high light transmittance as compared to the first encapsulation insulating layer IL1. The third encapsulation insulating layer IL3 may be an inorganic layer. The third encapsulation insulating layer IL3 may include a silicon oxide (SiOₓ) or a silicon oxy nitride (SiON). The third encapsulation insulating layer IL3 may be formed through a chemical vapor deposition process. Each of the first encapsulation insulating layer IL1, the second encapsulation insulating layer IL2, and the third encapsulation insulating layer IL3 may include a plurality of layers, but the present disclosure is not limited to an embodiment.

The input sensing layer ISL may include at least one conductive layer (or at least one sensor-conductive layer) and at least one insulating layer (or at least one sensor insulating layer). In an embodiment, the input sensing layer ISL may include a first insulating layer IS-IL1, a first conductive layer ICL1, a second insulating layer IS-IL2, a second conductive layer ICL2, and a third insulating layer IS-IL3. FIG. 6 briefly illustrates a conductive line of the first conductive layer ICL1 and a conductive line of the second conductive layer ICL2.

The first insulating layer IS-IL1 may be directly disposed on the display panel DP. The first insulating layer IS-IL1 may be an inorganic layer including at least one of a silicon nitride, a silicon oxy nitride, and a silicon oxide. Each of the first conductive layer ICL1 and the second conductive layer ICL2 may have a single-layer structure or have a multi-layer structure in which layers are laminated in the third direction DR3. The first conductive layer ICL1 and the second conductive layer ICL2 may include conductive lines that define a mesh-shaped electrode. The conductive line of the first conductive layer ICL1 and the conductive line of the second conductive layer ICL2 may or may not be connected through a contact hole passing through the second insulating layer IS-IL2. A connection relationship between the conductive line of the first conductive layer ICL1 and the conductive line of the second conductive layer ICL2 may be determined depending on the type of sensor formed in the input sensing layer ISL.

The first conductive layer ICL1 and the second conductive layer ICL2 having a single-layer structure may include a metal layer or a transparent conductive layer. The metal layer may include molybdenum, silver, titanium, copper, aluminum, or alloys thereof. The transparent conductive layer may include a transparent conductive oxide such as an indium tin oxide (ITO), an indium zinc oxide (IZO), a zinc oxide (ZnOₓ), or an indium zinc tin oxide (IZTO). In addition, the transparent conductive layer may include a conductive polymer such as poly(3,4-ethylenedioxythiophene) (PEDOT), metal nanowire, graphene, or the like.

The first conductive layer ICL1 and the second conductive layer ICL2 having a multi-layer structure may include metal layers. The metal layers may have, for example, a three-layer structure of titanium/aluminum/titanium. The conductive layer having a multi-layer structure may include at least one metal layer and at least one transparent conductive layer. The second insulating layer IS-IL2 may be disposed between the first conductive layer ICL1 and the second conductive layer ICL2. The third insulating layer IS-IL3 may cover the second conductive layer ICL2. In an embodiment of the present disclosure, the third insulating layer IS-IL3 may be omitted. The second insulating layer IS-IL2 and the third insulating layer IS-IL3 may include an inorganic layer or an organic layer.

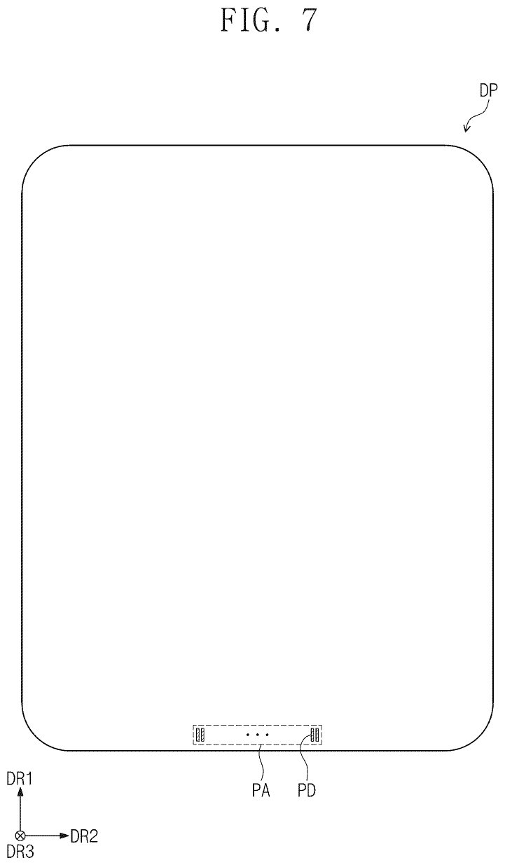

FIG. 7 is a plan view of the display panel according to an embodiment of the present disclosure. In detail, FIG. 7 is a plan view of the display panel DP when viewed from the third direction DR3.

Referring to FIG. 7, a pad electrode PD may be disposed on the rear surface of the display panel DP. In detail, the pad electrode PD may be disposed on the pad area PA. The pad electrode PD may be provided as a plurality of pad electrodes PD. The pad electrodes PD may be arranged in the second direction DR2.

The plurality of signal lines SGL (see FIG. 5) arranged on the display panel DP may be electrically connected to the main circuit board MCB of the circuit board FCB illustrated in FIG. 3 through the pad area PA. For example, the plurality of signal lines SGL may be arranged in the pad area PA and connected to the pad electrodes PD spaced apart from each other in the first direction DR1 through a connection electrode or the like. Although not illustrated, the pad electrodes PD may be arranged on the rear surface of the display panel DP and electrically connected to the circuit board FCB (see FIG. 2).

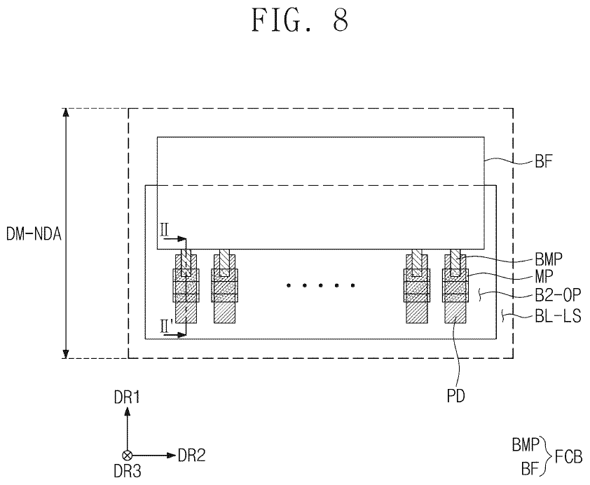

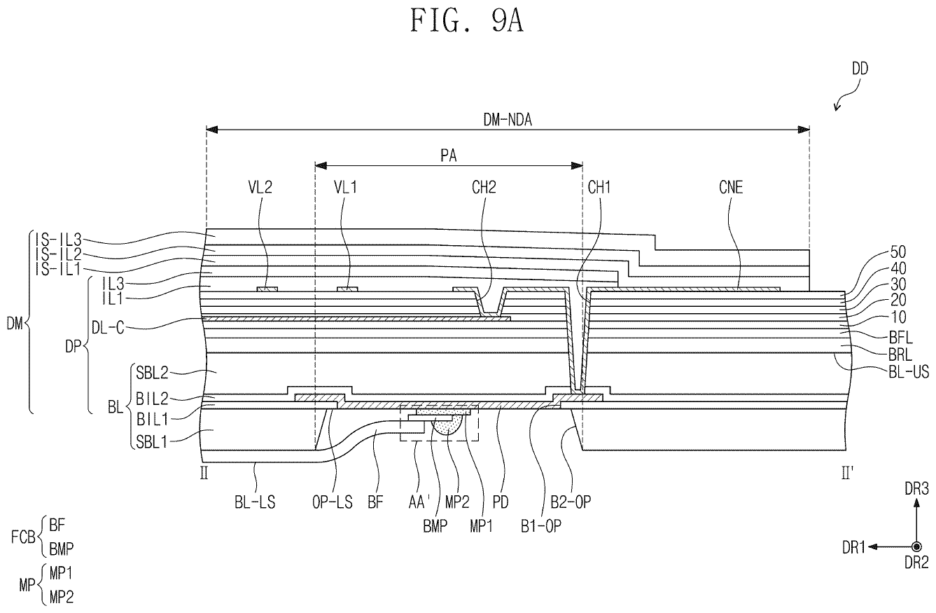

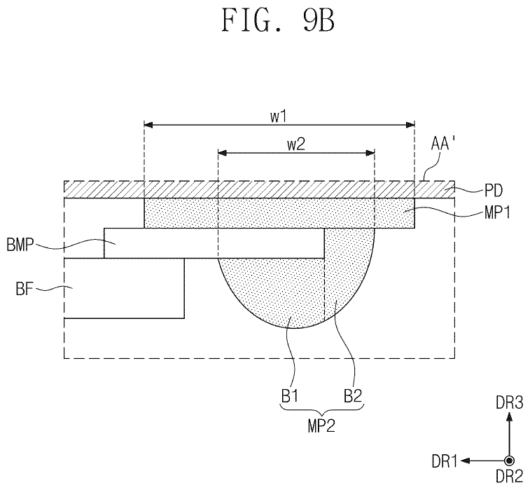

FIG. 8 is an enlarged view of a portion of the display device according to an embodiment of the present disclosure. FIG. 9A is a cross-sectional view of the display device along line II-II′ of FIG. 8. FIG. 9B is an enlarged view of area AA′ of FIG. 9A. FIGS. 8 and 9A are views illustrating a state in which the circuit board FCB is attached to the display panel DP. Hereinafter, descriptions duplicated with the above description may be omitted.

Referring to FIGS. 8 and 9A, the display device DD according to the present disclosure may include a connection electrode CNE and the plurality of pad electrodes PD. The connection electrode CNE is disposed on the same layer as the first connection pattern CNP1 illustrated in FIG. 6, and a portion of a data connection line DL-C, which overlaps the non-display area DM-NDA, is disposed on the same layer as the gate GT1 of the silicon transistor S-TFT illustrated in FIG. 6. The data connection line DL-C may be electrically connected to the data line DL (see FIG. 5).

The pad electrodes PD may be exposed to the outside through a lower surface BL-LS of the base layer BL for rear surface bonding with the circuit board FCB. However, the present disclosure is not limited thereto, and the pad electrodes PD may be exposed to the outside through a contact hole or the like without being directly exposed to the outside. The lower surface BL-LS of the base layer BL faces an upper surface BL-US of the base layer BL in the third direction DR3.

The base layer BL may include a first sub-base layer SBL1, a first base insulating layer BIL1, a second base insulating layer BIL2, and a second sub-base layer SBL2. The first base insulating layer BIL1 is disposed on the first sub-base layer SBL1, and the second base insulating layer BIL2 is disposed on the first base insulating layer BIL1 and covers the pad electrodes PD. The second sub-base layer SBL2 is disposed on the second base insulating layer BIL2.

The first sub-base layer SBL1 and the second sub-base layer SBL2 may include a synthetic resin material, for example, polyimide. The first base insulating layer BIL1 and the second base insulating layer BIL2 may include an inorganic material. For example, the first base insulating layer BIL1 and the second base insulating layer BIL2 may include a silicon nitride, a silicon oxy nitride, or a silicon oxide.

The first base insulating layer BIL1 is disposed on the first sub-base layer SBL1, and a first opening B1-OP through which portions of the pad electrodes PD are exposed is defined. The first sub-base layer SBL1 may be disposed under the first base insulating layer BIL1. The first sub-base layer SBL1 provides the lower surface BL-LS of the base layer BL, and a second opening B2-OP through which the pad electrodes PD are exposed to the outside of the display module DM is defined in the first sub-base layer SBL1. The second opening B2-OP may expose a portion of the first base insulating layer BIL1 to the outside. A size of the second opening B2-OP is larger than a size of the first opening B1-OP.

The pad electrodes PD may be embedded in the base layer BL. However, the present disclosure is not limited thereto, and the pad electrodes PD may be arranged on the lower surface BL-LS of the base layer BL. Even when the base layer BL includes a single-layer synthetic resin layer or a plurality of layers, the first opening B1-OP and the second opening B2-OP, which will be described below, may not be defined. The pad electrodes PD arranged on the lower surface BL-LS of the base layer BL may be connected to the conductive pattern disposed on the upper surface BL-US of the base layer BL through a contact hole passing through the base layer BL.

The connection electrode CNE may be connected to the pad electrodes PD through a first contact hole CH1 and connected to the data connection line DL-C through a second contact hole CH2. The first contact hole CH1 and the second contact hole CH2 may be arranged in the non-display area DM-NDA. The first contact hole CH1 may be formed by passing through portions of the plurality of insulating layers 10 to 50, the barrier layer BRL, the buffer layer BFL, and the base layer BL. The first contact hole CH1 may be connected to the pad electrodes PD while passing through the second base insulating layer BIL2 and the second sub-base layer SBL2 of the base layer BL. The second contact hole CH2 may be formed by passing from the second insulating layer 20 to the fifth insulating layer 50. The connection electrode CNE may be connected to the data line DL (see FIG. 5) through the second contact hole CH2.

The pad electrodes PD may extend in the first direction DR1 and may be arranged in the second direction DR2. However, the present disclosure is not limited thereto. A shape and arrangement of the pad electrodes PD are not limited to the illustration. The pad electrodes PD may overlap the non-display area DM-NDA. For example, the pad electrodes PD may be arranged in the pad area PA.

The circuit board FCB may be attached to the display panel DP in a bent state on the rear surface of the display panel DP. An adhesive layer may be disposed between the circuit board FCB and the lower surface BL-LS of the base layer BL. The circuit board FCB may be fixed to the lower surface BL-LS of the base layer BL by the adhesive layer.

The circuit board FCB may include a base film BF and a bump electrode BMP disposed on the base film BF. The base film BF may be formed integrally and electrically connected to the plurality of bump electrodes BMP. In this case, the base film BF may include a plurality of wiring lines therein. However, the present disclosure is not limited thereto, and the base film BF may be attached to the plurality of bump electrodes BMP and not electrically connected thereto. In this case, the base film BF may include a synthetic resin material, for example, polyimide. The bump electrodes BMP may be arranged on the base film BF.

The bump electrodes BMP may overlap the pad electrodes PD in a plan view. The bump electrodes BMP may be electrically connected to the pad electrodes PD. The bump electrodes BMP may be arranged to correspond to the pad electrodes PD. That is, the one bump electrode BMP may correspond to the one pad electrode PD. The bump electrodes BMP may extend in the first direction DR1 and may be arranged in the second direction DR2. An area of the pad electrodes PD in a plan view may be larger than an area of the bump electrodes BMP in a plan view.

Although not illustrated, an adhesive layer may be further disposed between the pad electrodes PD and the bump electrodes BMP and between the base film BF and the base layer BL. According to an embodiment, the adhesive layer may include an insulating material. In this case, the pad electrodes PD and the bump electrodes BMP may be electrically connected only through metal patterns MP.

The bump electrodes BMP may be electrically connected to the pad electrodes PD. In detail, the display device DD (see FIG. 2) according to the present disclosure may further include the metal patterns MP that electrically connect the bump electrodes BMP and the pad electrodes PD. The metal patterns MP may be arranged on the pad electrodes PD and the bump electrodes BMP to electrically connect the pad electrodes PD and the bump electrodes BMP. The metal patterns MP may be provided in a number corresponding to a number of each of the pad electrodes PD and the bump electrodes BMP.

Each of the metal patterns MP may be a pattern obtained by hardening a metal ink. The metal patterns MP may include solder paste. The metal patterns MP may be formed from the metal ink containing silver, copper, or the like. The metal patterns MP may be arranged on the pad electrodes PD exposed by the second opening B2-OP. The metal patterns MP may be formed by hardening and then patterning the metal ink. The metal patterns MP may be formed at a low temperature and electrically connect the pad electrodes PD and the bump electrodes BMP to each other and simultaneously bond the pad electrodes PD and the bump electrodes BMP without a high-temperature pressurizing process. A process of forming the metal patterns MP will be described in detail below.

Referring to FIGS. 9A and 9B, each of the metal patterns MP may include a first metal pattern MP1 and a second metal pattern MP2. The first metal pattern MP1 may be disposed between the pad electrodes PD and the bump electrodes BMP, and the second metal pattern MP2 may be disposed on the bump electrodes BMP and the first metal pattern MP1. The second metal pattern MP2 may overlap the first metal pattern MP1 in a plan view. The second metal pattern MP2 may be in contact with the first metal pattern MP1. The second metal pattern MP2 may be in contact with the first metal pattern MP1 at a portion thereof that overlaps the first metal pattern MP1 in a plan view. That is, the second metal pattern MP2 may be electrically connected to the first metal pattern MP1. According to an embodiment, the second metal pattern MP2 may include the same material as the first metal pattern MP1. The first metal pattern MP1 may be provided as a plurality of first metal patterns MP1, and the second metal pattern MP2 may be provided as a plurality of second metal patterns MP2. The first metal patterns MP1 and the second metal patterns MP2 may extend in the first direction DR1 and be arranged in the second direction DR2.

According to an embodiment of the present disclosure, the second metal pattern MP2 may include a first portion B1 and a second portion B2. The first portion B1 may overlap the bump electrodes BMP in a plan view, and the second portion B2 may not overlap the bump electrodes BMP in a plan view. The second portion B2 may cover side surfaces of the bump electrodes BMP. The second portion B2 may be in contact with the first metal pattern MP1 and electrically connected thereto.

A first width w1 of the first metal pattern MP1 may be defined as a width of the first metal pattern MP1 in the first direction DR1, and a second width w2 of the second metal pattern MP2 may be defined as a width of the second metal pattern MP2 in the first direction DR1. According to an embodiment of the present disclosure, the first width w1 of the first metal pattern MP1 may be larger than the second width w2 of the second metal pattern MP2. However, the present disclosure is not limited thereto, and the first width w1 may be equal to or smaller than the second width w2.

As the first metal pattern MP1 is formed between the pad electrodes PD and the bump electrodes BMP before the second metal pattern MP2 is formed, the bump electrodes BMP may be fixed by the first metal pattern MP1, and thus defects due to misalignment between the bump electrodes BMP and the pad electrodes PD may be prevented. Further, because the second metal pattern MP2 is formed after the first metal pattern MP1 is formed, the bump electrodes BMP may have different thicknesses in the third direction DR3, the second metal pattern MP2 may be permeated into a space between the bump electrodes BMP and the pad electrodes PD, and thus cracks that may occur due to the hardened second metal pattern MP2 may be prevented.

The first metal pattern MP1 according to the present disclosure may be in direct contact with the pad electrodes PD, and the first metal pattern MP1 may be electrically connected to the second metal pattern MP2. As compared to a case in which the second metal pattern MP2 is in direct contact with the pad electrodes PD and electrically connected thereto, an area in which the metal pattern MP is in contact with the pad electrodes PD may increase, and thus a resistance that may occur between the pad electrodes PD and the bump electrodes BMP may be reduced. As a result, the display device DD (see FIG. 2) having improved electrical reliability may be provided.

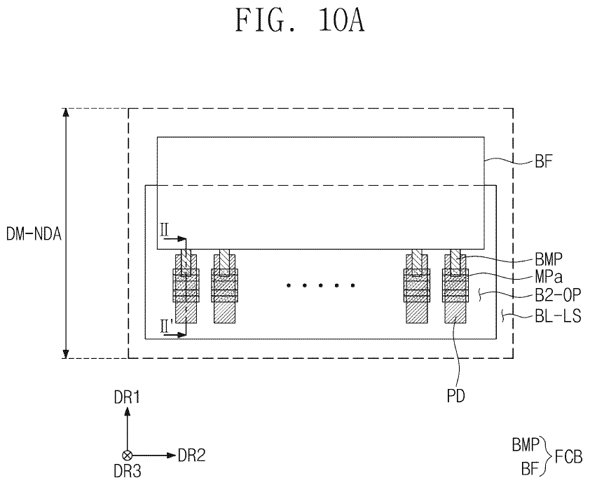

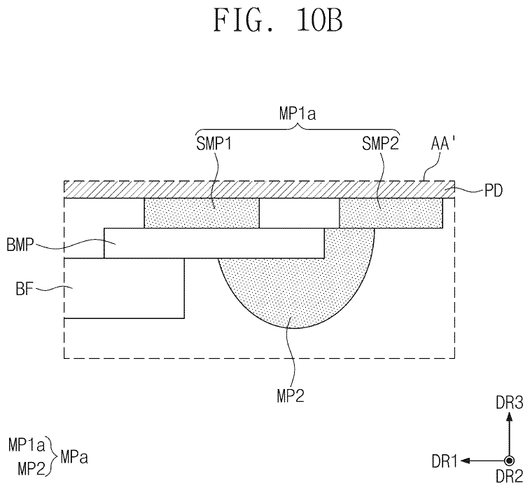

FIG. 10A is an enlarged view of the portion of the display device according to an embodiment of the present disclosure. FIG. 10B is an enlarged view of the display panel according to an embodiment in which area AA′ illustrated in FIG. 9A is enlarged. Hereinafter, a description duplicated with the above description may be omitted.

Referring to FIGS. 10A and 10B, metal patterns MPa may include a first metal pattern MP1a and the second metal pattern MP2. According to an embodiment of the present disclosure, the first metal pattern MP1a may include a first sub-metal pattern SMP1 and a second sub-metal pattern SMP2 that are spaced apart from each other. The first sub-metal pattern SMP1 and the second sub-metal pattern SMP2 may be spaced apart from each other in the first direction DR1. The first sub-metal pattern SMP1 may overlap the bump electrodes BMP in a plan view, and the second sub-metal pattern SMP2 may not overlap the bump electrodes BMP in a plan view. An empty space may be defined between the first sub-metal pattern SMP1 and the second sub-metal pattern SMP2. Although not illustrated, an adhesive layer or the like may be disposed in the empty space.

The first sub-metal pattern SMP1 may be in contact with the bump electrodes BMP, and the second sub-metal pattern SMP2 may be in contact with the second metal pattern MP2. The bump electrodes BMP may be electrically connected to the pad electrodes PD through the first sub-metal pattern SMP1 and the second sub-metal pattern SMP2. Although not illustrated, an adhesive layer including an insulating material may be disposed between the bump electrodes BMP and the first sub-metal pattern SMP1. In this case, the bump electrodes BMP may be electrically connected to each other through the second sub-metal pattern SMP2. As the first metal pattern MP1a according to the present disclosure includes the first sub-metal pattern SMP1 and the second sub-metal pattern SMP2, defects due to misalignment between the bump electrodes BMP and the pad electrodes PD may be prevented, and at the same time, a resistance that may occur between the pad electrodes PD and the bump electrodes BMP may be reduced.

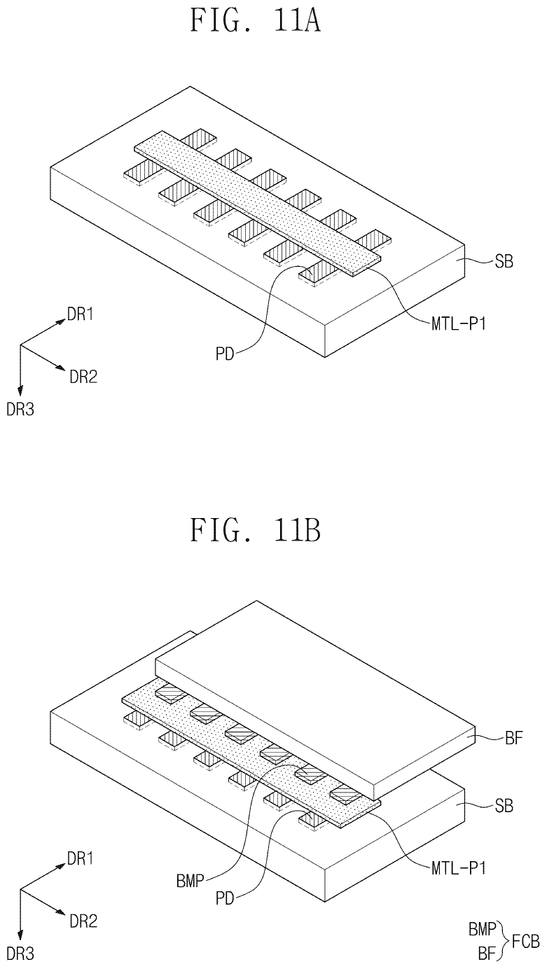

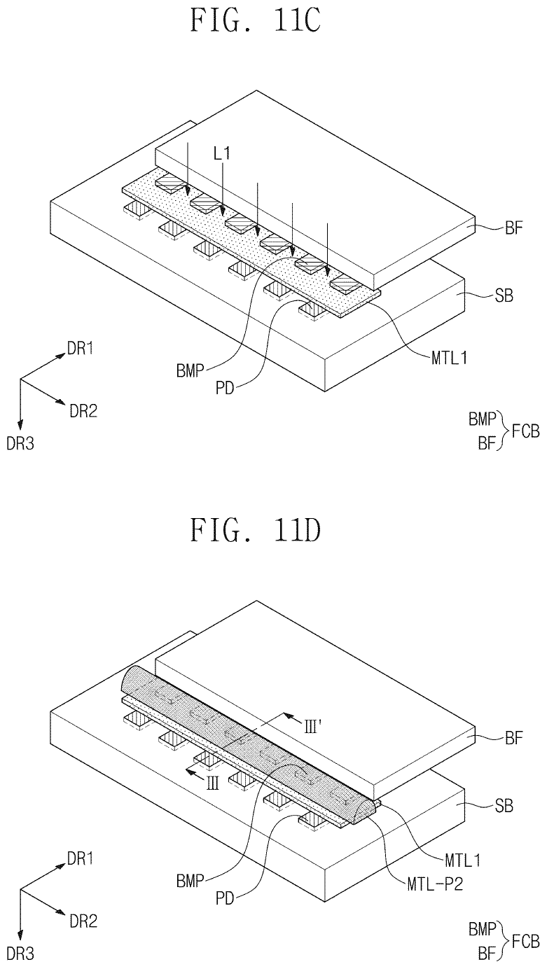

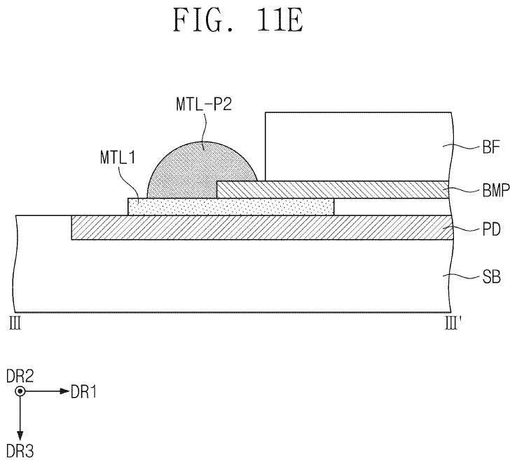

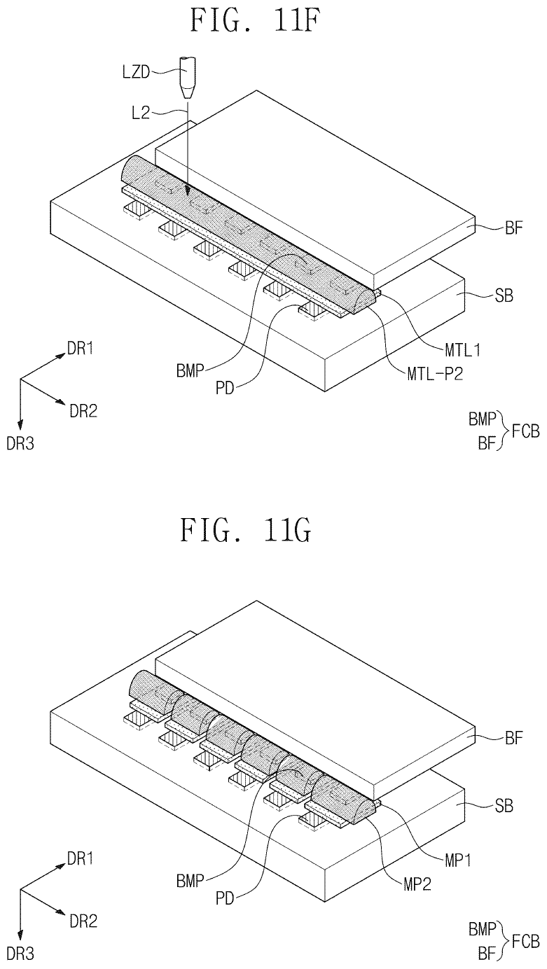

FIGS. 11A to 11G are views illustrating some of operations of a method of manufacturing the display device according to an embodiment of the present disclosure. Hereinafter, descriptions of the same components as the component described with reference to the accompanying drawings among components illustrated in FIGS. 11A to 11G may be omitted or simplified.

Referring to FIG. 11A, an operation of arranging a first preliminary metal layer MTL-P1 on a substrate SB may be performed. The pad electrodes PD may be embedded in the substrate SB. The pad electrodes PD may be exposed to the outside through an opening defined in the substrate SB. The substrate SB and the pad electrodes PD illustrated in FIG. 11A may correspond to the base layer BL and the pad electrodes PD illustrated in FIG. 9A. As illustrated in FIG. 9A, the pad electrodes PD may be exposed to the outside through the second opening B2-OP.

According to an embodiment of the present disclosure, the first preliminary metal layer MTL-P1 may be formed in a screen printing manner. For example, the first preliminary metal layer MTL-P1 may be printed using a squeegee after the metal ink is disposed on the pad electrodes PD. As a result, a thickness of the first preliminary metal layer MTL-P1 in the third direction DR3 may be uniform. The thickness of the first preliminary metal layer MTL-P1 in the third direction DR3 may be in a range of 0.1 mm or more and 0.2 mm or less.

Referring to FIG. 11B, an operation of arranging the circuit board FCB on the substrate SB and the first preliminary metal layer MTL-P1 may be performed. The circuit board FCB may include the base film BF and the bump electrodes BMP. The circuit board FCB illustrated in FIG. 11B may correspond to the circuit board FCB illustrated in FIG. 9A. The bump electrodes BMP may be arranged to overlap the pad electrodes PD in a plan view. The bump electrodes BMP may be in contact with the first preliminary metal layer MTL-P1.

Referring to FIG. 11C, an operation of hardening the first preliminary metal layer MTL-P1 (see FIG. 11B) to form a first metal layer MTL1 may be performed. The operation of hardening the first preliminary metal layer MTL-P1 may be performed by photo hardening. That is, the operation of hardening the first preliminary metal layer MTL-P1 may include an operation of irradiating a light L1 onto the first preliminary metal layer MTL-P1. A wavelength range of the light L1 may be 350 nm or more and 450 nm or less.

The bump electrodes BMP may be fixed from the first metal layer MTL1 through the operation of hardening the first preliminary metal layer MTL-P1. That is, the bump electrodes BMP may be aligned to correspond to the pad electrodes PD. Even in a subsequent process operation, the bump electrodes BMP may be fixed from the first metal layer MTL1 and may not move in the first direction DR1 or the second direction DR2.

Although not illustrated, an operation of cleaning the bump electrodes BMP may be further performed after the operation of forming the first metal layer MTL1. The operation of cleaning the bump electrodes BMP may include an operation of irradiating a laser onto the bump electrodes BMP to remove foreign substances formed on the bump electrodes BMP. In the operation of irradiating the laser onto the bump electrodes BMP, the first metal layer MTL1 may be disposed on the substrate SB to prevent the substrate SB from being damaged by the laser in an area that does not overlap the bump electrodes BMP.

Referring to FIGS. 11D and 11E together, a second preliminary metal layer MTL-P2 may be disposed on the bump electrodes BMP and the first metal layer MTL1. According to an embodiment of the present disclosure, the first preliminary metal layer MTL-P1 may be formed by an inkjet dispensing manner. The second preliminary metal layer MTL-P2 may be integrally connected and formed onto the bump electrodes BMP and the first metal layer MTL1. According to an embodiment of the present disclosure, the second preliminary metal layer MTL-P2 may have a non-uniform thickness. For example, the second preliminary metal layer MTL-P2 may have a non-uniform thickness in the second direction DR2. A cross section of the second preliminary metal layer MTL-P2 may include a hemispherical shape.

Before the second preliminary metal layer MTL-P2 is disposed on the bump electrodes BMP and the first metal layer MTL1, the first metal layer MTL1 may be formed between the bump electrodes BMP and the pad electrodes PD, and thus the second preliminary metal layer MTL-P2 may not permeate into a space that may be generated between the bump electrodes BMP and the pad electrodes PD. As a result, cracks that may occur due to hardening of the second preliminary metal layer MTL-P2 in the space between the bump electrodes BMP and the pad electrodes PD may be prevented.

Although not illustrated, an adhesive layer may be further disposed between the substrate SB and the base film BF. The substrate SB and the base film BF may adhere to each other through the adhesive layer. According to an embodiment of the present disclosure, the adhesive layer may include a non-conductive material. For example, the adhesive layer may be disposed between the substrate SB and the base film BF in the form of a non-conductive film. The adhesive layer may not overlap the first metal layer MTL1 in a plan view.

Referring to FIGS. 11F and 11G together, an operation of irradiating a laser L2 onto the first metal layer MTL1 and the second preliminary metal layer MTL-P2 may be performed. In detail, a laser irradiating device LZD may be disposed on the first metal layer MTL1 and the second preliminary metal layer MTL-P2, and thus the laser L2 may be irradiated to the first metal layer MTL1 and the second preliminary metal layer MTL-P2 arranged in an area not overlapping the pad electrodes PD and the bump electrodes BMP.

The first metal layer MTL1 may be patterned by the laser L2 to form the first metal pattern MP1, and the second preliminary metal layer MTL-P2 may be patterned by the laser L2 to form the second metal pattern MP2. The first metal pattern MP1 and the second metal pattern MP2 may correspond to the first metal pattern MP1 and the second metal pattern MP2 illustrated in FIG. 9A, respectively. The first metal pattern MP1 and the second metal pattern MP2 may electrically connect the pad electrodes PD and the bump electrodes BMP to each other. A number of each of the first metal patterns MP1 and the second metal patterns MP2 may correspond to a number of each the pad electrodes PD and the bump electrodes BMP.

Although not illustrated, an operation of hardening the second metal pattern MP2 may be further performed after the second metal pattern MP2 is formed. The operation of hardening the second metal pattern MP2 may be performed by photohardening as illustrated in FIG. 11C. That is, the operation of hardening the second metal pattern MP2 may include an operation of irradiating the light L1 (see FIG. 11C) onto the second metal pattern MP2. However, the present disclosure is not limited thereto, and the operation of hardening the second metal pattern MP2 may be performed before the operation of irradiating the laser L2 described in FIG. 11F is performed.

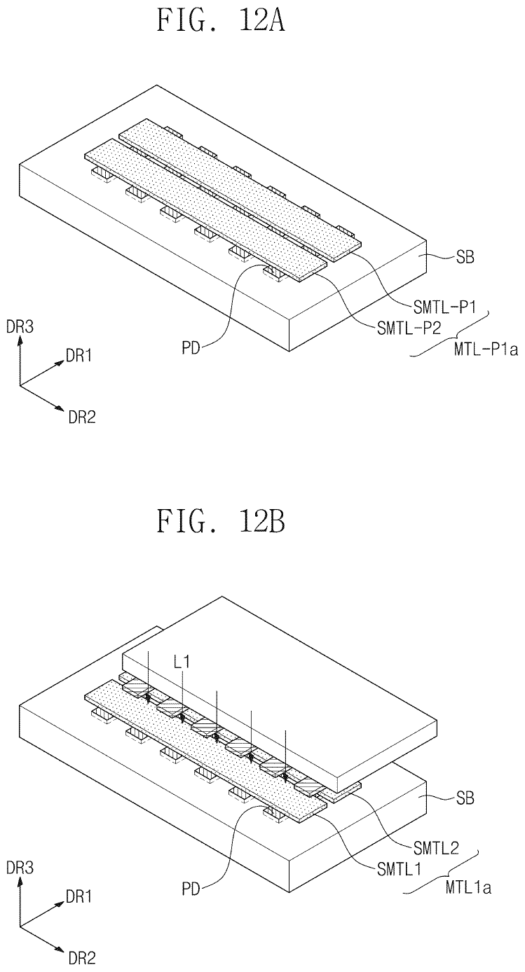

FIGS. 12A and 12B are views illustrating some of operations of a method of manufacturing the display device according to an embodiment of the present disclosure.

Referring to FIG. 12A, an operation of arranging a first preliminary metal layer MTL-P1a on the substrate SB may be performed. The first preliminary metal layer MTL-P1a may be formed by a screen printing manner. For example, the first preliminary metal layer MTL-P1a may be printed using a squeegee after the metal ink is disposed on the pad electrodes PD.

The first preliminary metal layer MTL-P1a may include a first preliminary sub-metal layer SMTL-P1 and a second preliminary sub-metal layer SMTL-P2 spaced apart from each other. The first preliminary sub-metal layer SMTL-P1 and the second preliminary sub-metal layer SMTL-P2 may extend in the second direction DR2, and the first preliminary sub-metal layer SMTL-P1 and the second preliminary sub-metal layer SMTL-P2 may be spaced apart from each other in the first direction DR1.

Referring to FIGS. 12A and 12B together, a first metal layer MTL1a including a first sub-metal layer SMTL1 and a second sub-metal layer SMTL2 may be formed by hardening the first preliminary sub-metal layer SMTL-P1 and the second preliminary sub-metal layer SMTL-P2. The operation of hardening the first preliminary sub-metal layer SMTL-P1 and the second preliminary sub-metal layer SMTL-P2 may be performed by photohardening. That is, the operation of hardening the first preliminary sub-metal layer SMTL-P1 and the second preliminary sub-metal layer SMTL-P2 may include an operation of irradiating the light L1 onto the first preliminary sub-metal layer SMTL-P1 and the second preliminary sub-metal layer SMTL-P2. The operation of hardening the first preliminary sub-metal layer SMTL-P1 and the operation of hardening the second preliminary sub-metal layer SMTL-P2 may be formed simultaneously.

The first sub-metal layer SMTL1 and the second sub-metal layer SMTL2 may be provided as the first sub-metal pattern SMP1 and the second sub-metal pattern SMP2 illustrated in FIGS. 10A and 10B through a subsequent process.

In a display device according to the present disclosure, a first metal pattern may be formed between pad electrodes and bump electrodes, and a second metal pattern may be formed on the bump electrodes and the first metal pattern. As the first metal pattern is formed between the pad electrodes and the bump electrodes before the second metal pattern is formed, the bump electrodes may be fixed by the first metal pattern, and thus defects due to misalignment with the pad electrodes may be prevented. Further, the bump electrodes have different thicknesses, and thus cracks that may be caused by a metal ink that is permeated into a space between the bump electrodes and the pad electrodes and is hardened may be prevented.

Although the description has been made above with reference to an embodiment of the present disclosure, it may be understood that those having ordinary skill in the art may variously modify and change the present disclosure without departing from the spirit and technical scope of the present disclosure described in the appended claims.

Thus, the technical scope of the present disclosure is not limited to the detailed description of the specification but should be defined by the appended claims.

What is claimed is:

1. A display device comprising:
a display panel including a base layer that defines an opening and a plurality of pad electrodes exposed to an outside through the opening;
a circuit board including a plurality of bump electrodes and electrically connected to the plurality of pad electrodes through the plurality of bump electrodes; and
a plurality of metal patterns configured to electrically connects the plurality of pad electrodes to the plurality of bump electrodes,
wherein each of the metal patterns includes:
a first metal pattern disposed between a pad electrode and a bump electrode; and
a second metal pattern disposed on the bump electrode and the first metal pattern.

2. The display device of claim 1, wherein the second metal pattern includes:
a first portion overlapping the bump electrode in a plan view; and
a second portion not overlapping the bump electrode in the plan view and configured to cover a portion of the first metal pattern.

3. The display device of claim 2, wherein the second portion is in contact with and electrically connected to the first metal pattern.

4. The display device of claim 1, wherein the first metal pattern overlaps the second metal pattern in a plan view.

5. The display device of claim 1, wherein a width of the first metal pattern is greater than a width of the second metal pattern.

6. The display device of claim 1, wherein the first metal pattern includes a first sub-metal pattern and a second sub-metal pattern spaced apart from each other in a direction in which the plurality of pad electrodes extend.

7. The display device of claim 6, wherein the first sub-metal pattern overlaps the bump electrode in a plan view, and
wherein the second sub-metal pattern does not overlap the plurality of bump electrodes in the plan view.

8. The display device of claim 6, wherein the second metal pattern is in contact with and electrically connected to the second sub-metal pattern.

9. The display device of claim 1, wherein the plurality of pad electrodes and the plurality of bump electrodes extend in a first direction and are arranged in a second direction intersecting the first direction.

10. The display device of claim 9, wherein a number of each of the first metal patterns and the second metal patterns correspond to a number of the bump electrodes,
wherein the plurality of first metal patterns and the plurality of second metal patterns are arranged in the second direction.

11. The display device of claim 1, wherein the display panel further includes a circuit layer disposed on the base layer and including at least one signal line electrically connected to the plurality of pad electrodes.

12. An electronic device comprising:
a housing;
an electronic module disposed inside the housing; and
a display device disposed to overlap the electronic module,
wherein the display device includes:
a display panel including a base layer that defines an opening and includes a plurality of pad electrodes exposed to an outside through the opening;
a circuit board including a plurality of bump electrodes and electrically connected to the plurality of pad electrodes through the plurality of bump electrodes; and
a plurality of metal patterns configured to electrically connect the plurality of pad electrodes and the plurality of bump electrodes, and
wherein each of the metal patterns includes:
a first metal pattern disposed between a pad electrode and a bump electrode; and
a second metal pattern disposed on the bump electrode and the first metal pattern.

13. A method of manufacturing a display device, the method comprising:
forming a first preliminary metal layer on a plurality of pad electrodes exposed through an opening defined in a base layer and arranged in a first direction;
providing a plurality of bump electrodes arranged on the first preliminary metal layer and overlapping the plurality of pad electrodes in a plan view;
hardening the first preliminary metal layer to form a first metal layer;
forming a second preliminary metal layer disposed on the plurality of bump electrodes and the first metal layer; and
forming a plurality of first metal patterns and a plurality of second metal patterns by patterning the first preliminary metal layer and the second preliminary metal layer,
wherein each of the pad electrodes and each of the bump electrodes electrically connect by a first metal pattern and a second metal pattern.

14. The method of claim 13, wherein, in the hardening of the first preliminary metal layer, the plurality of bump electrodes are coupled to the first metal layer.

15. The method of claim 13, wherein the forming of the second metal pattern includes hardening the second preliminary metal layer.

16. The method of claim 13, wherein, in the forming of the first preliminary metal layer, the first preliminary metal layer is formed in a screen printing manner.

17. The method of claim 13, wherein, in the forming of the second preliminary metal layer, the second preliminary metal layer is formed in an inkjet dispensing manner.

18. The method of claim 13, further comprising:
arranging an adhesive layer on the base layer before the providing of the plurality of bump electrodes.

19. The method of claim 13, wherein the first preliminary metal layer includes a first preliminary sub-metal layer and a second preliminary sub-metal layer spaced apart from each other in a direction in which the plurality of pad electrodes extend, and
wherein the first preliminary sub-metal layer overlaps the plurality of bump electrodes in the plan view, and the second preliminary sub-metal layer does not overlap the plurality of bump electrodes in the plan view.

20. The method of claim 19, wherein in the hardening of the first preliminary metal layer, hardening of the first preliminary sub-metal layer and hardening of the second preliminary sub-metal layer are simultaneously performed.
